(19) United States
(12) Patent Application Publication
(10) Pub. No.: US 2026/0255933 A1
(43) Pub. Date: Aug. 27, 2026

(54) METHOD FOR MANUFACTURING A CRYSTALLINE SILICON CARBIDE (SIC)-BASED DEVICE

(71) Applicant: COMMISSARIAT A L'ENERGIE ATOMIQUE ET AUX ENERGIES ALTERNATIVES, Paris (FR)

(72) Inventor: Florian DUPONT, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/489,746

(22) PCT Filed: Jun. 5, 2024
(86) PCT No.: PCT/EP2024/065392

§ 371 Date: Dec. 3, 2025

(30) Foreign Application Priority Data
Jun. 5, 2023 (FR) FR2305617

(51) Int. Cl. H10P 90/00; H10P 10/00

(52) U.S. Cl. CPC H10P 90/1916; H10P 10/128

(57) ABSTRACT

A method is provided for manufacturing a crystalline, preferably monocrystalline SiC-based device. The method includes combining: the use of a specific buffer layer, through its aspects which are refractory and inert to temperature and through its crystalline properties close to those of SiC, to grow the device, and the laser lift-off of the device by sacrificing the buffer layer, the latter having a thickness enabling a functional absorption of a laser lift-off radiation, while remaining sufficiently low to not have dislocations which can propagate to the device during its growth. The thermal balance is reduced, with respect to the known methods and the integrity of the device is best preserved, at least relative to what would be observed, if a thermal annealing, for example at a temperature greater than 400° C., had to be applied to lift off the device.

### TECHNICAL FIELD OF THE INVENTION

The present invention relates to the field of manufacturing substrates and other devices, each comprising a silicon carbide (“SiC” below), crystalline, preferably monocrystalline layer. Typically, such substrates and devices (called “SiC substrates” and “SiC devices” below, respectively) form or are intended to form all or some power components or devices integrating a transistor based on CMOS (Complementary Metal Oxide Semiconductor) technology.

### PRIOR ART

SiC is a semiconductor material commonly used in the industry, in particular, for manufacturing power electronics devices.

A so-called initial SiC substrate is the most adapted to growth, in particular epitaxial growth, of an SiC-based monocrystalline layer.

It could be considered to use other initial substrate, but this would pose different problems, among which:
a. The difficulty of ensuring an epitaxial growth of SiC under a useful polytype for the manufactured SiC device (typically, the 4H polytype),
b. The degradation of the quality of the crystalline structure of the crude SiC, in particular due to its difference of mesh parameters with the chosen initial substrate, and
c. The presence of stresses generated in the chosen initial substrate and SiC during and following its growth.

For these different reasons, the methods for growing an SiC monocrystalline layer generally implement monocrystalline SiC initial substrates; yet, it is found that the cost of these initial substrates is high, likewise, the cost of current SiC devices coming from such methods.

In order to reduce the production costs linked to manufacturing SiC-based substrates and other devices, manufacturing SiCOI (SiC On Insulator)-type substrates, by a technology known as SmartSiC™ has been developed by Soitec®. According to this technology, SiCOI-type substrates are made from a thin SiC layer detached from a SiC monocrystalline initial substrate by a Crystal Ion Slicing-type method.

However, the SmartSiC™ method requires an annealing for performing the detachment/slicing of the SiC monocrystalline layer and this prevents certain integrations, in particular, by hybridisation of said SiCOI-type substrates with a device integrating a transistor based on CMOS technology (called “CMOS device” below). It is further impossible to perform the SiC epitaxy on a substrate in which an ion implantation according to the SmartSiC™ method has been performed, as such an epitaxy assumes a thermal balance which would lead to the detachment of the epitaxially grown layer during its growth. It could be considered to perform the ion implantation provided by the SmartSiC™ method through the already crude SiC-based layers, therefore after the growth, but this would certainly damage the properties of an SiC device, through which the implantation would occur. It is probably for these reasons, that the SmartSiC™ method is only used for producing so-called thin template or seed layers, intended for SiC growth. Furthermore, it is impossible to lift off the SiCOI substrates produced by implementing the SmartSiC™ method, while transferring them onto temperature-sensitive substrates or devices, like a CMOS (Complementary Metal Oxide Semiconductor) substrate or device, due to the detachment of the SiCOI substrates at the ion implantation zone involving a high-temperature annealing, typically at a temperature substantially equal to 1100° C. Finally, the cost of the SiCOI substrates obtained by implementation of the SmartSiC™ method, even if it is lower than the cost of the SiC substrates obtained by other methods (for example, by grinding), is still significant.

It would therefore be desirable to propose a method for manufacturing substrates and other crystalline, preferably monocrystalline SiC-based devices, the implementation of which would be of a reduced cost, in particular from an initial crystalline, preferably monocrystalline SiC substrate, and/or with respect to the SmartSiC™ method.

### SUMMARY OF THE INVENTION

To achieve at least one of these aims, according to a first aspect, a method for manufacturing a device is provided, comprising at least one crystalline, preferably monocrystalline silicon carbide (SiC)-based, even constituted of crystalline, preferably monocrystalline silicon carbide (SiC) so-called layer of interest, the manufacturing method comprising the following steps:
a. Providing a crystalline, preferably monocrystalline SiC-based, even constituted of crystalline, preferably monocrystalline SiC so-called initial layer, then
b. Epitaxially growing, on the initial substrate, a so-called buffer layer with the basis of a material having, in its crystalline, preferably monocrystalline form:
   i. a parameter of equal mesh, plus or minus 6%, preferably plus or minus 2%, to a mesh parameter of crystalline, preferably monocrystalline SiC, with the basis of which the initial substrate is constituted, and
   ii. a melting point strictly greater than 1600° C., preferably greater than 2000° C., and even more preferably, greater than or substantially equal to 2500° C., and
   iii. until the buffer layer has a thickness strictly greater than 2 nm, preferably greater than or equal to 4 nm, and strictly less than twice, preferably substantially equal to or less than, a critical thickness Ec beyond which defects or dislocations appear in the crude buffer layer,
c. Epitaxially growing, on the buffer layer, at least the layer of interest, to obtain a stack successively comprising the initial substrate, the buffer layer and at least the layer of interest, the stack extending from a rear face carried by the initial substrate, up to a front face opposite the rear face, and
d. Providing a so-called receiver substrate, then
e. Transferring the stack through its front face onto the receiver substrate, then
f. Insolating the stack, preferably through its rear face, with a laser radiation having a wavelength more absorbed by the buffer layer than by the crystalline, preferably monocrystalline SiC, with the basis of which the initial substrate is constituted, the laser radiation being configured to alter the buffer layer, so as to detach the initial substrate from the rest of the stack, by at least partially sacrificing the buffer layer, and thus obtaining a device comprising at least the layer of interest transferred onto the receiver substrate.

The manufacturing method such as introduced above thus provides to combine:
a. the use, as an SiC seed layer in crystalline, preferably monocrystalline form, of a specific buffer layer, to form the device of interest (that which comprises at least the crystalline, preferably monocrystalline silicon carbide (SiC)-based, even constituted of crystalline, preferably monocrystalline silicon carbide (SiC) layer of interest, and
b. the laser lift-off of the device of interest, by at least partially sacrificing the buffer layer.

The thermal balance is reduced, with respect to the known methods, such that the integrity of the device of interest, as well as, if necessary, that of the initial substrate, being relatively unaltered, at least relative to what would be observed if a thermal annealing, for example, at a temperature greater than 400° C., needed to be applied to lift off the device of interest.

It is noted that it results from that above, that the method such as introduced above, preferably has no thermal annealing step, in particular, to lift off said device.

According to a second of its aspects, the invention relates to a use of the manufactured device, by implementation of the method such as introduced above, and comprising the epitaxial growth of crystalline, preferably monocrystalline SiC, on the layer of interest of the device, the layer of interest consisting of a thin layer. In this case, the manufacturing method makes it possible to manufacture a device constituted of a thin crystalline, preferably monocrystalline SiC layer, which can be used as a seed layer of a crystalline, preferably monocrystalline SiC-based substrate.

According to a third of its aspect, the invention relates to a use of the device manufactured by implementation of the method such as introduced above to obtain a SiC-based, epitaxially grown device, lifted off from the receiver substrate.

According to a fourth of its aspects, the invention relates to a use of the manufactured device by implementation of the method such as introduced above, to assemble the manufactured device with a CMOS-type device as a receiver substrate, if necessary, by electrically interconnecting to one another, the device and the CMOS-type device by respective reconnection zones of the device and of the CMOS-type device, the CMOS-type device being, for example, silicon-based.

### BRIEF DESCRIPTION OF THE FIGURES

The aims, objectives, as well as the features and advantages of the invention will best emerge from the detailed description of an embodiment of the latter and a few variants which are illustrated by the following accompanying drawings, in which:

FIGS. 1A to 1E represent different steps of an embodiment of the manufacturing method according to the first aspect of the invention.

FIGS. 2A and 2B represent different steps of a first variant of the embodiment which is illustrated in FIGS. 1A to 1E.

FIGS. 3A and 3B represent different steps of a second variant of the embodiment which is illustrated in FIGS. 1A to 1E.

FIGS. 4A and 4B represent different steps of a third variant of the embodiment which is illustrated in FIGS. 1A to 1E.

FIG. 5 represents a flowchart of another embodiment of the manufacturing method according to the first aspect of the invention relative to that illustrated in FIGS. 1A to 1E.

The drawings are given as examples, and are not limiting of the invention. They constitute principle schematic representations intended to facilitate the understanding of the invention, and are not necessarily to the scale of practical applications. In particular, the relative thicknesses of the different layers illustrated in the drawings are not representative of reality.

### DETAILED DESCRIPTION OF THE INVENTION

Before starting a detailed review of embodiments of the invention, optional features are stated below, which can optionally be used in association or alternatively:

According to an example, the manufacturing method can further comprise, following the detachment of the initial substrate from the rest of the stack, a step consisting of recovering the initial substrate, and if necessary, to provide it again. The initial substrate can thus be reused, if necessary, after at least one treatment, for example, chosen from among a chemical and chemical-mechanical polishing (CMP) treatment. The option of recycling the initial substrate makes it possible to greatly reduce the costs linked to the manufacture of a crystalline, preferably monocrystalline SiC-based device.

According to an example, the material with the basis of which the buffer layer is constituted, can be chosen from among:
a. TIN, VN, ZrN, TaN, NbN, and HfN, even MON, WN and CrN, and
b. TiC, VC, ZrC, TaC, NbC, and HfC, even MoC, WC and CrC,
c. Or a mixture of at least two of these chemical compounds.

According to an alternative example to the preceding one, the material with the basis of which the buffer layer can be constituted is chosen from among NbN, HfN and TiN, or a mixture of at least two of these chemical components.

According to an alternative example to the two preceding ones, the material with the basis of which the buffer layer can be constituted is niobium nitride (NbN).

According to an example, the buffer layer can be crude, by implementing at least one from among: a reactive sputtering, a pulsed laser deposition (PLD), a molecular beam epitaxy (MBE), or a chemical vapour deposition (CVD).

According to an example, the thickness of the buffer layer can be between 1.5 and 15 nm, preferably between 3 and 12 nm, and will, for example, be substantially equal to 4 nm or 10 nm.

According to an example, the critical thickness of the buffer layer can be between 4 nm and 100 nm, preferably between 10 nm and 20 nm, and will typically be substantially equal to 15 nm.

According to an example, the step of epitaxially growing said at least one layer of interest can comprise the implementation of a chemical vapour deposition (CVD).

According to an example, the device can consist of said layer of interest and form a seed layer.

According to an alternative example to the preceding one, the step of epitaxially growing said at least the layer of interest can comprise, further to the growth of said layer, the growth of other layers to form, together with said layer of interest, an SiC-based epitaxially grown device, comprising, for example, at least one from among a power component and a radiofrequency component, such as a diode or a transistor, in particular, a field effect diode or transistor. According to this example, the growth of the different layers of the device can be done, such that at least one of these layers, or at least one zone of at least one of these layers is doped, of the N type or of the P type, if necessary, with different atoms of a layer to another or of a zone to another. Still according to this example, each layer can constitute all or part of an SiC-based component; it cannot, in particular, be homogeneous and comprise, in addition to semiconductor elements, conductor elements, such as conductive tracks, forming, for example, a redistribution layer (RDL) and dielectric elements, for example, with the basis of an oxide of a semiconductor material, for example, silicon oxide or an epoxy resin.

According to an example, the transfer of the stack through its front face on the receiver substrate can comprise, or consist of, a step of bonding the stack through its front face on the receiver substrate, the bonding step preferably being carried out by implementing a technique enabling the bonding to resist conditions, in particular of temperature, intended to be met during subsequently steps of manufacturing and/or treating and/or assembling the device. The bonding of the stack, through its front face on the receiver substrate, can thus be done through at least one bonding layer. Complementarily or alternatively, the SiC-based epitaxially grown device and the receiver substrate each comprising reconnection zones flush with the face through which it is opposite the other, the step of bonding the stack through its front face on the receiver substrate can comprise at least one electrical contacting of a reconnection zone of the SiC-based epitaxially grown device with a reconnection zone of the receiver substrate, the bonding being hybrid, for example.

According to an example, the receiver substrate can be chosen from among:
a. A polycrystalline SiC-based substrate,
b. A substrate with the basis of a material having a thermal expansion coefficient substantially equal to the thermal expansion coefficient of crystalline, preferably monocrystalline SiC,
c. A substrate integrating a transistor, for example, based on CMOS technology,
d. A silicon-based substrate,
e. A metal substrate, and
f. Preferably, when the device is finalised before the insolation step, a substrate comprising a base wafer, thermal grease, and a thermal dissipator.

According to an example, the material with the basis of which the buffer layer is formed can have an absorbance of at least 10%, preferably of at least 20%, greater than an absorbance of a crystalline, preferably monocrystalline SiC layer, of the same thickness as the buffer layer, for the chosen wavelength of laser radiation and for the critical thickness Ec of the buffer layer.

According to an example, the wavelength of the laser radiation can be located in the visible or the infrared.

It is specified that, in the scope of the present invention, the terms “on”, “surmounts”, “covers”, “underlying”, “opposite” and their equivalents do not necessarily mean “in contact with”. Thus, for example, the deposition of a first layer on a second layer, does not compulsorily mean that the two layers are directly in contact with one another, but means that the first layer at least partially covers the second layer, by being directly in contact with it, or by being separated from it by at least one other layer or at least one other element.

A layer can moreover be composed of several sublayers of one same material or of different materials.

By a layer with the basis of a material A, this means a layer comprising this material A and optionally other materials.

By a parameter “substantially equal to/greater than/less than” a given value, this means that this parameter is equal to/greater than/less than the given value, plus or minus 20%, even plus or minus 10% of this value. By a parameter “substantially between” two given values, this means that this parameter is, as a minimum, equal to the smallest given value, plus or minus 20%, even plus or minus 10% of this value, and, as a maximum, equal to the largest given value, plus or minus 20%, even plus or minus 10% of this value.

When use is made of the term “(mono) crystalline”, the fact of putting “mono” between brackets indicates that, if the material thus qualified, is preferably fully monocrystalline, its crystalline structure comprises, all the same, and relatively essentially, defects that a person skilled in the art will seek to reduce as much as possible, for a better quality result.

By “critical thickness” of an epitaxially grown layer, this means the thickness beyond which defects or dislocations appear in the crude layer. This thickness can, for example, be determined in an indicated manner in the article by Dai, Y., et al., entitled “Engineering of the Curie temperature of epitaxial Sr1-xBaxTiO3 films via strain” and appeared, in 2016, in “Journal of Applied Physics”, vol. 120, p. 114101. The present invention is considered to be accommodated with methods for measuring the critical thickness which would be more accurate and/or which would come to be developed.

In the present description, a material is considered as absorbent at a wavelength A, as soon as it absorbs at least 20% of a light radiation of wavelength A, preferably at least 50% and advantageously at least 70%. These absorption percentages are however given for information of one of the parameters to be considered to evaluate the capacity of a layer of a material to be heated under laser insolation; other parameters are, if necessary, to be considered as the thickness of the layer (typically, when the thickness of the layer increases, its absorption also increases) or the power of the laser, which can impact, in particular, on the indicated absorption percentages. A material can be considered as transparent at a wavelength \ as soon as it transmits at least 90% of a light radiation of wavelength A, preferably at least 95%.

Several embodiments of the invention implementing successive steps of the transfer method are described below. Unless explicitly mentioned, the term “following” does not necessarily imply, even if this is generally preferred, that the steps immediately follow one another, intermediate steps being able to separate them.

Moreover, the term “step” means the carrying out of a part of the method, and can mean a set of substeps.

Furthermore, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time, and in the sequence of phases of the method.

In the present patent application, the thickness of a layer is taken along a direction normal to the main extension plane of the layer. The relative terms “on”, “surmounts”, “under”, “underlying”, “inserted” refer, unless mentioned otherwise, to positions taken along the direction normal to the main extension plane of the layer.

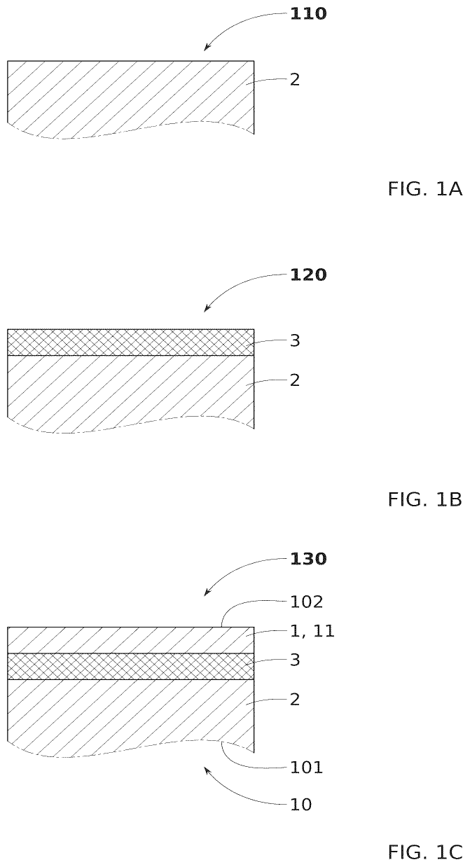

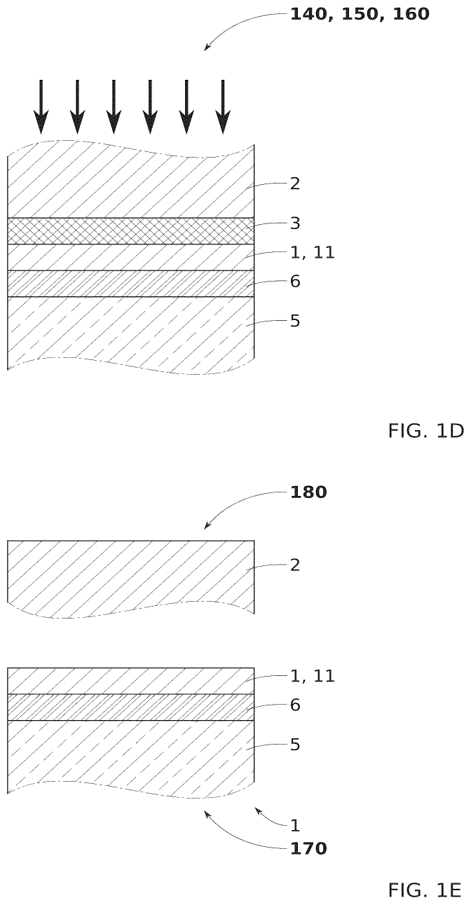

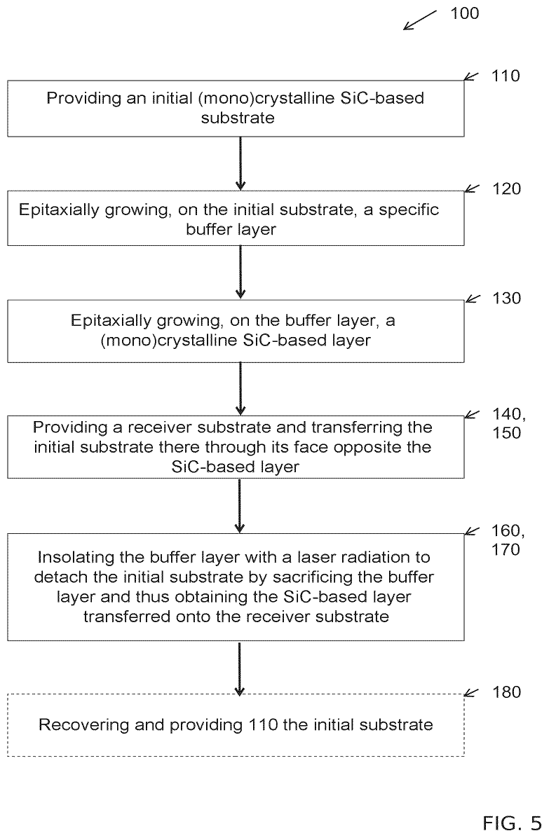

The manufacturing method, according to an embodiment of the first aspect of the invention, is described below in reference to FIGS. 1A to 1E and 5. More specifically, this is a method 100 for manufacturing a device 1 comprising at least one (mono) crystalline silicon carbide SiC-based, even constituted of (mono) crystalline silicon carbide SiC layer 11.

The method 100 provides the provision 110 of an initial (mono) crystalline SiC-based, even constituted of (mono) crystalline SiC substrate 2, and the provision 140 of a receiver substrate 5.

More specifically, the initial substrate 2 can be constituted of a trench or “wafer”, or of a part of such a trench, made of (mono) crystalline silicon carbide SiC. This provision step 110 is therefore potentially according to the corresponding step of the SmartSiC™ method.

From the initial substrate 2, the method 100 comprises a step consisting of epitaxially growing 120, and on the initial substrate 2, a specific buffer layer 3. More specifically, the buffer layer 3 is specific in that it is constituted with the basis of a material having, in its monocrystalline form:
a. a parameter of equal mesh, plus or minus 6%, preferably plus or minus 2%, to a parameter of mesh of the (mono) crystalline SiC with the basis of which the initial substrate (2) is constituted, and
b. a melting point strictly greater than 1600° C., preferably greater than 2000° C., and even more preferably, greater than or substantially equal to 2500° C.

Thus, the material with the basis of which the buffer layer 3 is constituted gives the buffer layer 3:
a. the capacity to propagate the crystalline structure of the (mono) crystalline SiC to a (mono) crystalline SiC-based layer 11 of interest, which, as will be seen below, is intended to be crude 130 on the buffer layer 3, and
b. refractory and inert aspects to significant temperature variations, to, in particular, enable its epitaxial growth 130 of the (mono) crystalline SiC-based layer 11 of interest, without these variations inducing a change of nature or of nominal composition of the buffer layer 3.

The buffer layer 3 is more specifically crude 120 until it has a thickness strictly greater than 1.5 nm, preferably greater than or equal to 3 nm, and strictly less than twice, preferably substantially equal to or less than, a critical thickness Ec beyond which defects or dislocations appear in the crude 120 buffer layer 3. In other words, if the thickness of the buffer layer remains less than its critical thickness, which depends mainly on its nature (composition) and on its crystalline structure, it is ensured that the structure of the buffer layer 3 is coherent with the structure of the initial substrate 2. The buffer layer 3 can, for example, be crude 120 until it has a thickness substantially equal to 4 nm.

The thickness of the buffer layer 3 is thus limited lower and greater. Typically, the thickness of the buffer layer 3 will be substantially between 1.5 nm and 15 nm, preferably between 3 and 12 nm, and will, for example, be substantially equal to 4 nm or 10 nm, and/or the buffer layer 3 will be constituted, with the basis of a material for which the critical thickness Ec of the buffer layer 3 will be between 4 nm and 100 nm, preferably between 10 nm and 20 nm, and will typically be substantially equal to 15 nm.

On the one hand, the thickness of the buffer layer 3 must indeed be sufficient to enable a functional absorption, of a laser radiation of determined wavelength, such that the buffer layer 3 constitutes a sacrificial layer under insolation by said laser radiation.

On the other hand, the thickness of the buffer layer 3 must remain sufficiently low to not have, defects and dislocations such as they would propagate to the layer 11 of interest during its growth, which would prevent the obtaining of a monocrystalline layer 11 of interest or at the very least, would degrade the monocrystalline structure of said layer 11 of interest, which is desired to be the best possible quality.

Several materials can make it possible to give these functionalities to the buffer layer 3. More specifically, the material with the basis of which the buffer layer 3 is constituted, can be chosen from among:
a. TIN, VN, ZrN, TaN, NbN, and HfN, even MON, WN and CrN, and
b. a mixture of at least two of these chemical compounds.

The table below consults a few significant parameters in the scope of implementation of the manufacturing method 100, according to a first aspect of the invention, for different nitrides from among those mentioned above. It can be considered first, that each of these nitrides has properties which are refractory and inert to temperature, in particular, because they all have a melting point greater than 2000° C. It can also be observed that the mesh parameter of each of these nitrides does not significantly differ from the mesh parameter of (mono) crystalline SiC; more specifically, all of these nitrides have an equal mesh parameter, plus or minus 6%, to the mesh parameter of (mono) crystalline SiC. It is also noted that the critical thickness Ec determined for each of these nitrides can be relatively low, and in particular, less than or equal to a few nanometres, for some of them, which do not make them preferable candidates, since a low critical thickness Ec induces a low thickness of the buffer layer 3, and therefore a low absorption of the laser radiation supposed to sacrifice it. Therefore, it results from the table below, that the material that constitute titanium nitride and niobium nitride are the best candidates from among the nitrides that the table mentions.

TABLE

| | | Crystalline properties | | | | |
|---|---|---|---|---|---|---|
| | Thermal | | Mesh | | Optical properties | |
| | properties | Mesh | parameters | Critical | Absorption | Absorption |
| Materials | Melting point | parameter | with SiC | thickness | (k) at | at Ec and |
| Composition | (° C.) | (Å) | ratio | Ec | 1200 nm | 1200 nm |
| TiN | 2930 | 2.998 | −2.50% | 4 nm | 5 | 22% |
| VN | 2050 | 2.918 | −5.20% | 1 nm | 3.6 | 5% |
| ZrN | 2980 | 3.229 | 5% | 1 nm | | 5% |
| NbN | 2573 | 3.054 | −0.70% | 15 nm | | 54% |
| HfN | 3310 | 3.196 | 3.90% | 2 nm | | 10% |
| TaN | 3090 | 2.906 | −5.50% | 1 nm | | 5% |

It is noted, in this case, that if the critical thickness Ec of a titanium nitride layer is only 4 nm, it can be considered to grow a titanium nitride-based buffer layer 3 having a thickness greater than 4 nm, even going up to 8 nm, without defects or dislocations being created there, which are such that they would not enable the growth of an SiC-based monocrystalline layer 11 of interest from its exposed surface. Furthermore, the absorbance of a titanium nitride-based layer of a thickness substantially less than 8 nm and greater than the absorbance of a layer of the same nature, but of a thickness substantially equal to 4 nm, and therefore greater than 22% (see table 1), which can be satisfactory.

It is also noted that it is possible to express the absorbance that the buffer layer 3 must have relative to the absorbance that a monocrystalline SiC layer of the same thickness would have, and to pose as a preference, that the material with the basis of which the buffer layer 3 is formed, has an absorbance of at least 10%, preferably of at least 20%, greater than an absorbance of such a monocrystalline SiC layer, for the chosen wavelength of the laser radiation and for the critical thickness Ec of the buffer layer 3. According to an alternative formulation, the absorption coefficient of the buffer layer 3 must be greater than the absorption coefficient of SiC. Ideally, the buffer layer 3 must be able to be considered as absorbent at the wavelength of the laser radiation, while the stack 10 and the initial substrate 2 must be able to be considered as transparent to the wavelength of the laser radiation, if they had the same thickness as the buffer layer 3.

If titanium nitride TiN and hafnium nitride HfN seem to be good candidates, fulfilling the specifications described above, they however has a difference in mesh parameters with monocrystalline SiC which induces a low critical thickness; and it results from the table above, that the best candidate, from among the nitrides that the table mentions, is niobium nitride NbN, which has both a high melting point, a mesh parameter very close to that of monocrystalline SiC, and therefore a significant critical thickness Ec leaving to be considered to be able to grow the buffer layer 3 up to a thickness substantially equal to 30 nm, at which the buffer layer 3 would have an absorbance:
a. greater than 54%, even though such an absorbance is already very satisfactory, and
b. of a nature to guarantee the sacrificial functionality of the buffer layer 3 under laser insolation at a wavelength of 1200 nm.

It is noted that the absorbance measurements/data which are mentioned in the table above correspond to those obtained for a laser radiation having a wavelength equal to 1200 nm, located in the infrared. Infrared laser radiations having other wavelengths can be considered, as soon as they make it possible to sacrifice the buffer layer 3, preferably without degrading the integrity of the other layers. Potentially, the same applies for laser radiations, the wavelengths of which are located in the visible spectrum (typically between 380 and 750 nanometres).

It is also noted that the parameters discussed in the paragraphs above and consulted in the table are defined at ambient temperature, even at ambient temperature and pressure.

Alternatively or complementarily to the abovementioned nitrides, the buffer layer 3 can be constituted with the basis of certain carbides, and in particular, with the basis of carbides chosen from among TiC, VC, ZrC, TaC, NbC, and HfC, even MoC, WC and CrC.

Moreover, the buffer layer 3 can be crude by implementing any current epitaxial growth technique adapted to the scenario, and in particular at least one from among: a reactive sputtering, a pulsed laser deposition (PLD), a molecular beam epitaxy (MBE) or a chemical vapour deposition (CVD).

Still in reference to FIGS. 1A to 1E and 5, the manufacturing method 100 according to the embodiment illustrated comprises, following the epitaxial growth 120 of the buffer layer 3, a step consisting of epitaxially growing 130, on the buffer layer 3, at least the abovementioned layer 11 of interest. The layer 11 of interest can be crude by implementing, according to the ordinary skills of a person skilled in the art, any current epitaxial growth technique adapted to the scenario, and typically a chemical vapour deposition (CVD).

It is noted, in this case, that if the step 130 comprises, as a minimum, the epitaxial growth of a thin monocrystalline SiC layer as a layer 11 of interest, it can comprise other technological microelectronics steps, whether before and/or after the epitaxial growth of the thin layer 11. It is understood that, if the buffer layer 3 must be able to support temperatures, being able to reach up to 1600° C. or more, necessary for the epitaxial growth of SiC, certain technological steps, among these potentially comprised by the step 130 of the manufacturing method 100 can require higher temperatures; the buffer layer 3, and in particular, the material with the basis of which it is constituted, will thus preferably be chosen to support these higher temperatures.

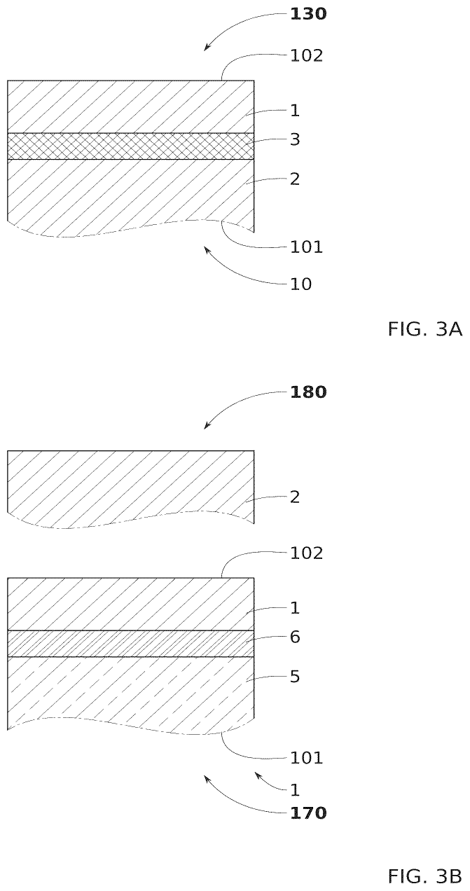

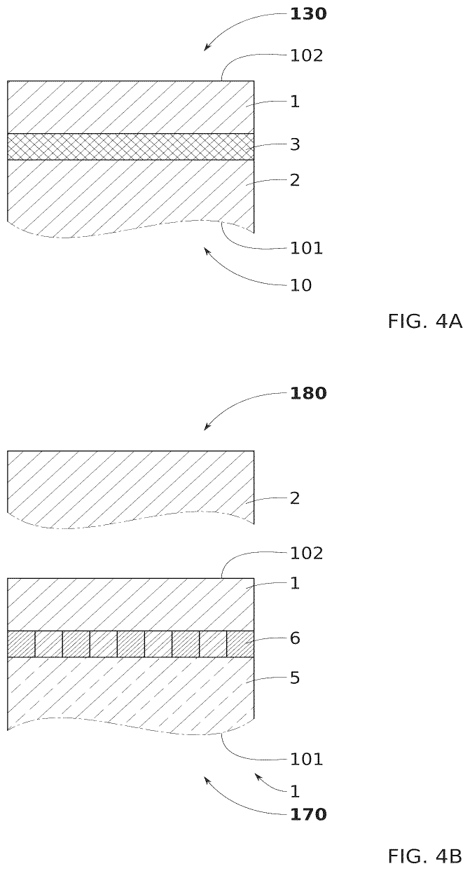

It is already understood, in this case, that the device 1 to be manufactured comprises, as a minimum, the monocrystalline SiC-based layer 11 of interest, but that the device 1 can comprise other layers, with the basis of the same semiconductor material or with the basis of at least one other semiconductor material, so as to constitute, for example, an SiC-based epitaxially grown device 1, and the growth of each layer with the basis of a semiconductor material of the device 1 can be done, such that it is, at least by zone, doped, of N type or of P type, if necessary, with different atoms from one layer to another or from one zone to another. Such an SiC-based epitaxially grown device 1 can thus comprise, for example:
a. at least one from among a power component and a radiofrequency component, such as a diode or a transistor, in particular a field effect diode or transistor, but also
b. conductor elements, such as conductive tracks, forming, for example, a redistribution layer (RDL) and dielectric elements, for example, with the basis of an oxide of a semiconductor material, typically silicon oxide or an epoxy resin. Below, this point will be referred back to, in reference to FIGS. 3A, 3B, 4A and 4B.

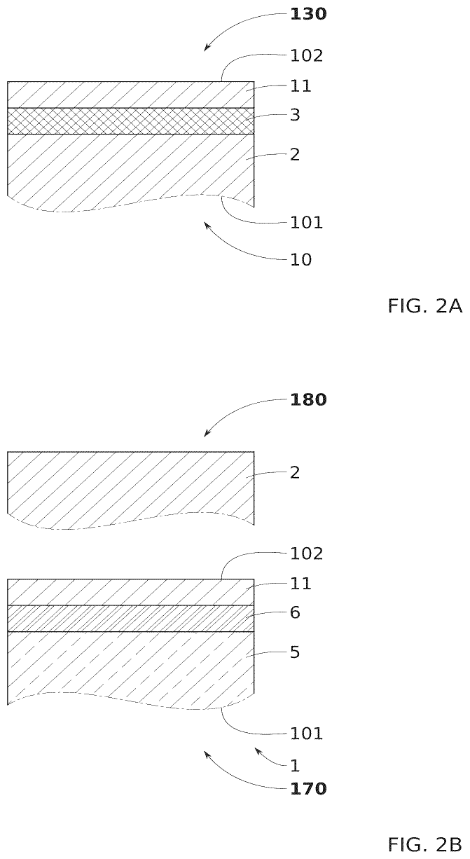

When the device 1 to be manufactured is constituted of the monocrystalline SiC-based layer 11 of interest, it can be considered as forming a seed layer, i.e. a layer on which it will be possible to epitaxially grow other monocrystalline SiC-based layer, typically to obtain a monocrystalline SiC-based substrate. Such is the embodiment illustrated in FIGS. 2A and 2B.

Nevertheless, following the growth 130 of the device 1, or at the very least, a part of this device 1 that the layer 11 of interest constitutes, a stack 10 is obtained which successively comprises the initial substrate 2, the buffer layer 3 and at least the layer 11 of interest of the device 1 to be manufactured, the stack 10 extending from a rear face 101 constituted by the initial substrate 2 up to a front face 102 opposite the rear face 101, and constituted of at least one part of the device 1.

Still in reference to FIGS. 1A to 1E and 5, the manufacturing method 100 according to the embodiment illustrated comprises, following the growth 130 of the device 1, or at the very least, a part of this device 1 that the layer 11 of interest constitutes, a step consisting of transferring 150 the stack 10 through its front face 102 onto the receiver substrate 5 provided 140.

More specifically, the transfer of the stack 10 through its front face 102 on the receiver substrate 5 can comprise, or consist of, a step of bonding the stack 10 through its front face 102 on the receiver substrate 5. The bonding step is preferably carried out by implementing a technique enabling the bonding to resist the conditions already stated above, in particular the temperature conditions, which are intended to be met, in particular during subsequent steps of manufacturing and/or treating and/or assembling the device 1.

It is noted in this case, that the receiver substrate 5 can be chosen from among:
a. a polycrystalline SiC-based substrate, the cost of which is lesser than a monocrystalline SiC-based substrate, and which advantageously has a thermal expansion coefficient close to monocrystalline SiC;
b. a substrate with the basis of a material having a thermal expansion coefficient substantially equal to the thermal expansion coefficient of (mono) crystalline SiC, even the (mono) crystalline SiC-based substrate;
c. a substrate integrating a transistor, for example, based on CMOS technology;
d. a silicon-based substrate, potentially integrating a transistor, for example, based on CMOS technology;
e. a metal substrate; at low cost, this type of substrate could have, if necessary, just one mechanical support function, for protecting transistors and/or releasing heat; and
f. preferably, when the device 1 is finalised before the insolation step 160, a substrate comprising a base wafer (for which the stack 10 is intended to be transferred onto the receiver substrate 5), of thermal grease, and a thermal dissipator; it could thus be a so-called packaging substrate, and thus transfer the stack, by bonding, directly on a packaging substrate.

As FIGS. 1A to 1E illustrate, the bonding of the stack 10 through its front face 102 on the receiver substrate 5 can be done through one or more bonding layers 6, according to the ordinary skills of a person skilled in the art. For example, a bonding layer 6 can be deposited on the front face 102 of the layer 11 of interest, or more generally of the device 1, which is constituted with the basis of a glue, for example organic, such as BCB or SU-8, and a bonding layer 6 constituted with the basis of one same glue or a different glue can be deposited on the receiving surface of the receiver substrate 5, such that the transfer 150 consists of bonding the two bonding layers 6 together. In this context, it is understood that the receiver substrate 5 can constitute a transfer substrate or equivalently, a temporary handle. There are plenty of other alternative means to the preceding example of bonding the stack 10 through its front face 102 on the receiver substrate 5; and the following can be mentioned as examples: a direct bonding, a eutectic bonding, etc. The adapted bonding will be chosen by a person skilled in the art according to the application, and in particular, to the need for electrical connection(s) or not, and/or for maintaining temperature. For example, if it is sought to return to an SiC epitaxy after lift-off of the stack 1 and transfer onto the receiver substrate 5, a direct bonding will rather be favoured, than a bonding through SU-8 or BCB which does not maintain the temperature linked to SiC epitaxy.

Still in reference to FIGS. 1A to 1E and 5, the manufacturing method 100 according to the embodiment illustrated comprises, following the transfer 150 of the stack 10 onto the receiver substrate 5, a step consisting of insolating 160 the stack 10 with the abovementioned laser radiation, having a wavelength more absorbed by the buffer layer 3 than by (mono) crystalline SiC with the basis of which the initial substrate 2 is constituted. The wavelength of the laser radiation will typically be chosen in the transparency range of (mono) crystalline SiC and/or, for example, substantially equal to 1200 nm.

Preferably, and as FIGS. 1A to 1E illustrate, the insolation 160 of the buffer layer 3 is preferably done through the rear face 101 of the stack 10, such that the layer 11 of interest, and more generally, the device 1 to be manufactured, is not directly exposed to the laser radiation, but rather, the initial substrate 2 which is, in principle, concentrated in the monocrystalline SiC-based substrate, and therefore which has, in principle, no functionalities potentially negatively affected by the abovementioned laser radiation.

Whether it is done, or not, through the rear face 101 of the stack 10, the insolation 160 must be configured to lead to the detachment of the initial substrate 2 from the rest of the stack 10 by at least partially sacrificing the buffer layer 3, and to the obtaining 170 of the device 1 comprising at least said layer 11 of interest and being transferred onto the receiver substrate 5, with or without bonding layer(s) 6.

The manufacturing method 100 such as described above thus provides the laser lift-off of the device 1 of interest by at least partially sacrificing the buffer layer 3. More specifically, the energy from the laser radiation is absorbed by the buffer layer 3, which has the effect of heating it. Under the effect of this heating, the buffer layer 3 is at least partially broken down into liquid and gaseous form. The gaseous part is dissipated, while at least one part of the liquid part can remain in contact with the upper face of the initial substrate 2 and/or with the lower face of the layer 11 of interest. Potential residues, in particular liquids, of the buffer layer 3, can be cleaned during a subsequent step not represented in the figures. For example, this cleaning can comprise dry or wet etching and/or CMP steps. This makes it possible to fully remove the buffer layer 3 residues on the surface of the initial substrate 2 and/or of the layer 11 of interest, without altering the surface or the structure of the latter.

This step of detaching the layer 11 of interest by altering the buffer layer 3 requires, as already mentioned above, a buffer layer 3 of a sufficient thickness to enable a functional absorption of the insolated laser radiation 160, while remaining sufficiently low to not have, defects and dislocations such that they would propagate to the device 1 of interest during its growth, in particular, during step 130.

The thermal balance of the manufacturing method 100 such as described above is reduced, with respect to the known methods, and in particular, relative to the SmartSiC™ method (the lift-off annealing of which is typically done at a temperature of 1100° C.), such that the integrity of the device 1 of interest, as well as, if necessary, that of the initial substrate 2, are relatively unaltered, at least relative to what would be observed, if a thermal annealing, for example, at a temperature greater than 400° C., even greater than 1000° C., had to be applied to lift off the device 1 of interest from the initial substrate 2.

It is noted that it results from that above, that the method 100 such as introduced above, preferably does not have a thermal annealing step, in particular to lift off the device 1 of interest from the initial substrate 2.

Following the detachment 170 of the initial substrate 2 from the rest of the stack 10, the manufacturing method 100 according to the embodiment illustrated in FIG. 5 can comprise a step consisting of recovering 180 the initial substrate 2, and if necessary, to provide 110 it again. The initial substrate 2 can thus be reused, if necessary, after at least one treatment, for example, chosen from among a chemical treatment and a chemical-mechanical polishing (CMP). The option of recycling the initial substrate 2 makes it possible to greatly reduce the costs linked to the manufacture of a (mono) crystalline SiC-based device 1.

The manufacturing method 100 such as described above in reference to FIGS. 1A to 1E and 5 can be used in different ways. Without claiming to be exhaustive, three different uses of the manufacturing method 100 according to the first aspect of the invention are illustrated in FIGS. 2A and 2B for the first, in FIGS. 3A and 3B for the second, and in FIGS. 4A and 4B for the third.

The first considered use consists, as already discussed above, of reducing the device 1 of interest to the single layer 11 of interest. In this case, the manufacturing method makes it possible to manufacture a device 1 constituted of a (mono) crystalline SiC layer 11 of interest which can be used as a seed layer, for example, of a (mono) crystalline SiC-based substrate. In this case, the receiver substrate can advantageously be polycrystalline SiC-based, and be encapsulated, if necessary (one or more layers deposited around or on polycrystalline SiC); the cost of such a receiver substrate is lesser than a monocrystalline SiC-based substrate and advantageously has a thermal expansion coefficient close to that of monocrystalline SiC. In this way, technological microelectronics steps which would come to be applied on the device 1 following its transfer 150 onto the receiver substrate 5 would not necessarily involve too significant dilatation differences between the device 1 and the receiver substrate 5. It is noted that, for this first use, the bonding between the layer 11 of interest and the receiver substrate 5 must be chosen, so as to resist the temperatures necessarily reached to grow monocrystalline SiC, typically temperatures substantially equal to, even slightly greater than 1600° C.

In reference to FIGS. 3A and 3B, the second considered use aims to obtain, initially, an SiC-based epitaxially grown device 1 transferred onto the receiver substrate 5. It can thus be advantageous that the manufacturing method 100 comprises, following the detachment of the initial substrate 2 from the rest of the stack 10, a step (not represented) consisting of lifting off the device 1 from the receiver substrate 5, if necessary, by sacrificing one or more bonding layers 6. For example, at least one bonding layer 6 can be with the basis of a cross-linkable polymer, for example under a UV radiation, so as to decrease its adhesion energy, and enable the lift-off of the device 1 of interest from the receiver substrate 5. It is noted that, before this lift-off, the manufacturing method 100 according to the first aspect of the invention can comprise technological microelectronics steps aiming to complete, even finalise, the device 1 of interest, the receiver substrate 5 thus typically acting as a transfer substrate or equivalently, a temporary handle and the bonding interface 6 thus needing to resist the implementation conditions of said technological steps. The second considered use aims to therefore obtain, secondly, an SiC-based epitaxially grown device 1 detached from any other component. It is thus possible to bond the SiC-based epitaxially grown device 1, for example, on a silicon-based substrate, in particular to process (or equivalently, treat through microelectronics techniques) the exposed face of the SiC-based epitaxially grown device 1.

In reference to FIGS. 4A and 4B, the third considered use consists of an integration of an SiC-based epitaxially grown device 1 such as manufactured 100, through its assembly with a CMOS-type device, in particular as a receiver substrate 5. If necessary, the assembly brings the electrical interconnection to one another of the device 1 and of the CMOS-type device through respective reconnection zones of the SiC-based epitaxially grown device 1 and of the CMOS-type device. The bonding layer(s) 6 such as illustrated in FIG. 4B thus preferably comprise zones with the basis of a dielectric material surrounding electrical reconnection zones. It is noted that the CMOS-type device is, for example, silicon-based, to show that it is possible to thus assemble different devices with the basis of semiconductor materials to one another. Further, it is noted that this type of assembly, considered to meet the ordinary skills of a person skilled in the art, can advantageously, in certain cases, be done cold, for example, by hybrid bonding. A transfer of an SiC-based epitaxially grown device 1 on a CMOS-type device is thus made possible by the implementation of the manufacturing method 100 described above. This option is not offered by the SmartSiC™ method, the Crystal Ion Slicing-type detachment is necessarily done hot.

It results from the above that the manufacturing method 100 according to the first aspect of the invention enables at least one from among:
a. the provision of high-quality and low-cost monocrystalline SiC-based substrates,
b. The low-cost production of monocrystalline SiC-based epitaxially grown devices, and
c. The hybridisation of monocrystalline SiC-based epitaxially grown devices on an, in particular, silicon-based CMOS-type device.

The invention is not limited to the embodiments described above, and extends to all the embodiments covered by the invention.

1. A method for manufacturing a device comprising at least one so-called crystalline, preferably monocrystalline silicon carbide (SiC)-based, even constituted of crystalline, preferably monocrystalline silicon carbide (SIC) layer of interest, the manufacturing method comprising the following steps:
Providing a so-called crystalline, preferably monocrystalline SiC-based, even constituted of crystalline, preferably monocrystalline SiC initial substrate, then
Epitaxially growing, on the initial substrate, a so-called buffer layer with the basis of a material having, in the crystalline, preferably monocrystalline form:
i. a mesh parameter equal, plus or minus 6%, preferably plus or minus 2%, to a mesh parameter of crystalline, preferably monocrystalline SiC, with the basis of which the initial substrate is constituted, and
ii. a melting point strictly greater than 1600° C., preferably greater than 2000° C., and even more preferably, greater than or substantially equal to 2500° C., and melting point strictly greater than 1600° C., preferably greater than 2000° C., and even more preferably, greater than or substantially equal to 2500° C., and
until the buffer layer has a thickness strictly greater than 2 nm, preferably greater than or equal to 4 nm, and strictly less than twice, preferably substantially equal to or less than, a critical thickness Ec beyond which defects or dislocations appear in the crude buffer layer,
Epitaxially growing, on the buffer layer, at least the layer of interest, to obtain a stack successively comprising the initial substrate, the buffer layer and at least the layer of interest, the stack extending from a rear face carried by the initial substrate, up to a front face opposite the rear face, and
Providing a so-called receiver substrate, then
Transferring the stack through its front face onto the receiver substrate, then
Insolating the stack, preferably through its rear face, with a laser radiation having a wavelength more absorbed by the buffer layer than by the crystalline, preferably monocrystalline SiC, with the basis of which the initial substrate is constituted, the laser radiation being configured to alter the buffer layer, so as to detach the initial substrate from the rest of the stack, by at least partially sacrificing the buffer layer, and thus obtaining a device comprising at least the layer of interest transferred onto the receiver substrate.

2. The method according to claim 1, further comprising, following the detachment of the initial substrate from the rest of the stack, a step consisting of recovering the initial substrate, and if necessary, to provide it again.

3. The method according to claim 1, wherein the material with the basis of which the buffer layer is constituted is chosen from among:
TIN, VN, ZrN, TaN, NbN, and HfN, even MON, WN and CrN, and
TiC, VC, ZrC, TaC, NbC, and HfC, even MoC, WC and CrC,
Or a mixture of at least two of these chemical components.

4. The method according to claim 1, wherein the material with the basis of which the buffer layer is constituted is chosen from among NbN, HfN and TiN, or a mixture of at least two of these chemical compounds.

5. The method according to claim 1, wherein the material with the basis of which the buffer layer is constituted is niobium nitride (NbN).

6. The method according to claim 1, wherein the thickness of the buffer layer (3) is between 1.5 and 15 nm, preferably between 3 and 12 nm, and will, for example, be substantially equal to 4 nm or 10 nm.

7. The method according to claim 1, wherein the device consists of said layer of interest and forms a seed layer.

8. The method according to claim 1, wherein the step of epitaxially growing said at least the layer of interest comprises, further to the growth of said layer, the growth of other layers to form, together with said layer of interest, an SiC-based epitaxially grown device, comprising, for example, at least one from among a power component and a radiofrequency component, such as a diode or a transistor, in particular, a field effect diode or transistor.

9. The method according to claim 1, wherein the transfer of the stack through its front face onto the receiver substrate comprises, or consists of, a step of bonding the stack through its front face onto the receiver substrate, the bonding step preferably being carried out by implementing a technique enabling the bonding to resist conditions, in particular of temperature, intended to be met during subsequently steps of manufacturing and/or treating and/or assembling the device.

10. The method according to claim 9, wherein the bonding of the stack through its front face on the receiver substrate is done through at least one bonding layer.

11. The method according to claim 8, wherein, the SiC-based epitaxially grown device and the receiver substrate each comprising reconnection zones flush with the face through which it is opposite the other, the step of bonding the stack through its front face on the receiver substrate comprises at least one electrical contacting of a reconnection zone of the SiC-based epitaxially grown device with a reconnection zone of the receiver substrate (5), the bonding being hybrid, for example.

12. The method according to claim 1, wherein the receiver substrate is chosen from among:
A polycrystalline SiC-based substrate,
A substrate with the basis of a material having a thermal expansion coefficient substantially equal to the thermal expansion coefficient of crystalline, preferably monocrystalline SiC,
A substrate integrating a transistor, for example, based on CMOS technology,
A silicon-based substrate,
A metal substrate, and
Preferably, when the device is finalised before the insolation step, a substrate comprising a base wafer, thermal grease, and a thermal dissipator.

13. The method according to claim 1, wherein the material with the basis of which the buffer layer is formed has an absorbance of at least 10%, preferably of at least 20%, greater than an absorbance of a crystalline, preferably monocrystalline SiC layer, of the same thickness as the buffer layer, for the chosen wavelength of the laser radiation and for the critical thickness Ec of the buffer layer.

14. The use of the device manufactured by implementation of the method according to claim 1 comprising the epitaxial growth, of crystalline, preferably monocrystalline SiC, on the layer of interest of the device, the layer of interest consisting of a thin layer.

15. The use of the method according to claim 1, to obtain an SiC-based epitaxially grown device lifted off from the receiver substrate.

16. The use of the method according to claim 1, to assemble the device manufactured with a CMOS-type device as a receiver substrate, if necessary by electrically interconnecting to one another, the device and the CMOS-type device by respective reconnection zones of the device and of the CMOS-type device, the CMOS-type device being, for example, silicon-based.
